(19) United States
(12) Patent Application Publication
(10) Pub. No.: US 2024/0107899 A1
(43) Pub. Date: Mar. 28, 2024

(54) SUPERCONDUCTING VACUUM-BRIDGED JOSEPHSON JUNCTIONS

(71) Applicant: IQM Finland Oy, Espoo (FI)

(72) Inventors: Wei Qiu, Espoo (FI); Wei Liu, Espoo (FI); Tianyi Li, Espoo (FI)

(21) Appl. No.: 18/371,685

(22) Filed: Sep. 22, 2023

(30) Foreign Application Priority Data
Sep. 23, 2022 (FI) 20225827

(51) Int. Cl. H10N 60/12; H10N 60/01; H10N 60/80; H10N 69/00

(52) U.S. Cl. CPC H10N 60/12; H10N 60/0912; H10N 60/805; H10N 69/00

(57) ABSTRACT

The invention relates to the field of superconducting integrated circuits. The invention includes an integrated circuit device comprising a substrate, a Josephson junction on the substrate, external electrodes on the substrate and spaced apart from the Josephson junction, and bridge connections connecting the Josephson junction to the external electrodes. The invention also includes a method for manufacturing such an integrated circuit device.

### TECHNICAL FIELD

The invention relates to the field of superconducting integrated circuits, in particular to superconducting devices including Josephson junctions, for example those used in quantum processing units.

### BACKGROUND

Losses arising from interfaces between different materials in a superconducting device including a Josephson junction result in poorer performance of the Josephson junction. In particular, when the Josephson junction is used as part of a physical qubit, e.g. a transmon qubit, the losses lead to decreases qubit performance, including lower coherence time.

### SUMMARY OF THE INVENTION

According to a first aspect of the invention, an integrated circuit device is provided. The integrated circuit device comprises a substrate, a Josephson junction on the substrate, external electrodes on the substrate and spaced apart from the Josephson junction, and bridge connections connecting the Josephson junction to the external electrodes.

The Josephson junction may be a component of a superconducting qubit. The superconducting qubit may be a transmon qubit, gmon qubit, or a fluxmon qubit. The integrated circuit device may be a quantum processing unit.

The Josephson junction may have been formed by shadow evaporation. The Josephson junction may be a cross type Josephson junction.

The Josephson junction may be an Al/AlOₓ/Al junction.

The Josephson junction may be spaced apart from the external electrodes such that no part of the Josephson junction is in direct contact with the external electrodes.

The Josephson junction may comprise a first layer and a second layer, a first bridge connection is in direct contact with the first layer of the Josephson junction and a first external electrode only, and a second bridge connection is in direct contact with the second layer of the Josephson junction and second external electrode only.

The first layer and second layer of the Josephson junction may comprise aluminium and a barrier layer disposed between the first layer and second layer may comprise aluminium oxide.

According to a second aspect of the invention, a method of fabricating an integrated circuit device is provided. The method comprises:
forming a Josephson junction and external electrodes on a substrate such that the Josephson junction is spaced apart from the external electrodes;
depositing a resist over the substrate, Josephson junction and external electrodes;
patterning the resist such that contact pads on the Josephson junction and external electrodes are exposed, and such that the patterned resist between the contact pads defines bridge connection support portions;
depositing a superconducting thin film over the resist such that the thin film is in direct electrical contact with the contact pads; and
forming bridge connections by removing the resist and superconducting thin film except for the superconducting thin film deposited on the contact pads and over the bridge connection support portions.

Forming the external electrodes may comprise depositing a metal layer on the substrate and patterning the metal layer to form the external electrodes and expose the substrate in areas not covered by the external electrodes.

Forming the Josephson junction may comprise a double angle evaporation and lift-off process.

The resist may be patterned using electron beam lithography or extended photolithography.

The method may further comprise, prior to depositing the superconducting thin film, performing a wet-etch and/or dry-etch to clean the exposed contact pads.

Patterning the resist may comprise exposing a first contact pad on a first layer of the Josephson junction, exposing a second contact pad on a second layer of the Josephson junction, exposing a third contact pad on a first external electrode, and exposing a fourth contact pad on a second external electrode.

The patterned resist may comprise a first bridge connection support portion extending between the first contact pad and the third contact pad, and a second bridge connection support portion extending between the second contact pad and the fourth contact pad.

Forming bridge connections may comprises forming a first bridge connection over the first bridge connection support portion, the first bridge connection being in direct contact with the first layer of the Josephson junction and a first external electrode only and forming a second bridge connection over the second bridge connection support portion, the second bridge connection being in direct contact with the second layer of the Josephson junction and second external electrode only.

The Josephson junction may be spaced apart from the external electrodes such that no part of the Josephson junction is in direct contact with the external electrodes.

A first layer and second layer of the Josephson junction may comprise aluminium and a barrier layer disposed between the first layer and second layer may comprise aluminium oxide.

The method may further comprises forming further components of a superconducting qubit on the substrate.

According to a third aspect of the invention, an integrated circuit device is provided. The integrated circuit device is produced according to the method described above.

### BRIEF DESCRIPTION OF THE DRAWINGS

FIG. 1 is a cross section of a superconducting device including a Josephson junction formed by shadow evaporation according to the state of the art.

FIG. 2A is a perspective view of a substrate on which a Josephson junction has been formed by shadow evaporation.

FIG. 2B is a cross-section of the structure shown in FIG. 2A.

FIG. 3A is a perspective view of the substrate of FIG. 2A after a resist has been formed on the upper surface.

FIG. 3B is a cross-section of the structure shown in FIG. 3A.

FIG. 4A is a perspective view of the substrate and resist shown in FIG. 3A after bridge connection support portions have been formed in the resist.

FIG. 4B is a cross-section of the structure shown in FIG. 4A.

FIG. 5A is a perspective view of the substrate and resist shown in FIG. 4A after deposition of a superconducting thin film over the, resist and bridge connection support portions and exposed contact pads.

FIG. 5B is a cross-section of the structure shown in FIG. 5A.

FIG. 6A is a perspective view of the substrate, Josephson junction and bridge connections after lift-off of the resist and superconducting thin film.

FIG. 6B is a cross-section of the structure shown in FIG. 6A.

FIG. 7 is a flow diagram depicting the method of manufacturing a semiconductor device shown in FIGS. 2A and 2B to FIGS. 6A and 6B.

### DETAILED DESCRIPTION OF THE INVENTION

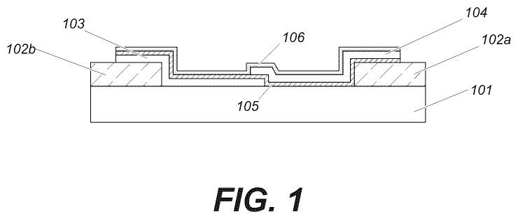

FIG. 1 is a cross section of a superconducting device including a Josephson junction, which is formed by a prior art shadow evaporation process. The Josephson junction is formed at the interface between a first layer 103, a barrier layer 105, and a second layer 104. The first and second layers 103, 104 extend away from the Josephson junction interface and are connected to external electrodes 102a, 102b. The external electrodes 102a, 102b are “external” to the Josephson junction in that they are not part of the Josephson junction per se, i.e. not the first layer, barrier layer, or second layer. However, the external electrodes 102a, 102b may be part of an integrated circuit component referred to as a “Josephson junction” in that they are used to form external connections, i.e. with other components. In other words, the first layer 103 and second layer 104 of the Josephson junction are connected to the external electrodes 102a, 102b and only to the external electrodes 102a, 102b. The first and second layers 103, 104, the barrier layer 105 and the external electrodes are located on a substrate 101, e.g. a silicon wafer. The upper surface of the barrier layer 105 and of the second layer 104 are covered by an oxidation layer 106. The first layer 103 of the Josephson junction may also be referred to as a “base electrode”, and the second layer 104 of the Josephson junction may also be referred to as a “counter electrode”.

Parasitic effects, e.g. two-level systems, that affect the performance of the Josephson junction arise at the interfaces between at least:
1) the external electrode 102a and the barrier layer 105
2) the external electrodes 102a, 102b and the substrate 101
3) the first layer 103 and the substrate 101
4) the first layer 103 and the external electrode 102b
5) the external electrodes 102a, 102b and surrounding gas, e.g. air
6) the barrier layer 105 and oxide(s) formed on the surface of the substrate 101.

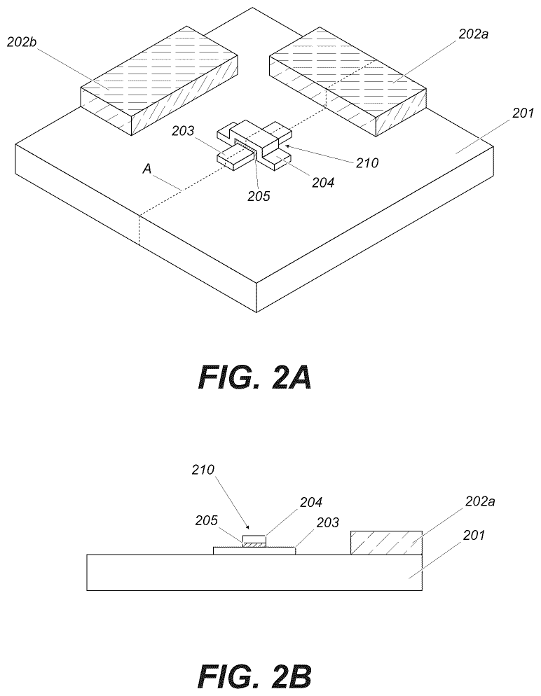

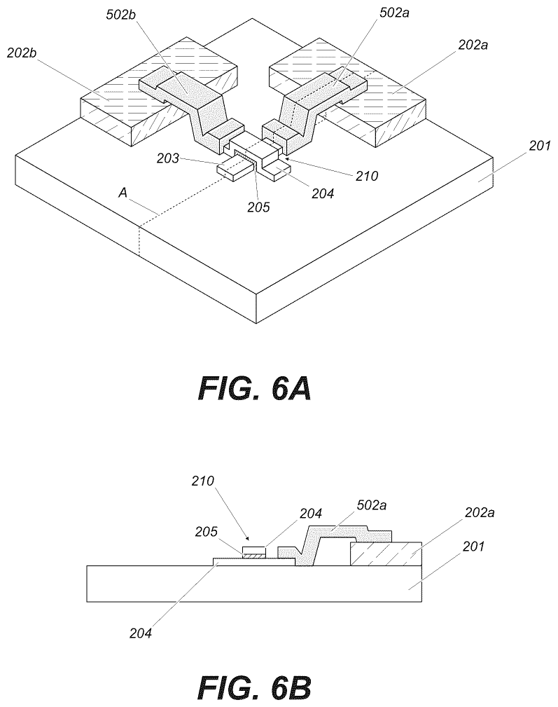

The present invention includes an integrated circuit device employing bridge connections in order to remove or reduce the size of these interfaces, thereby reducing parasitic effects in the superconducting device by forming bridged electrodes 502a, 502b between the external electrodes 102a, 102b and the first and second layers 103, 104. The present invention also includes a method of manufacturing the device. The bridged electrodes 502a, 502b are depicted in detail in FIGS. 6A and 6B and a method of forming the bridged electrodes 502a, 502b is depicted in FIGS. 2A and 2B to FIGS. 5A and 5B.

FIGS. 2A and 2B show a first step of the method of manufacturing the integrated circuit device of the present invention. FIG. 2A is a perspective view of a substrate 201 on which a Josephson junction 210 has been fabricated by shadow evaporation, e.g. as described in CMOS compatible fabrication methods for submicron Josephson junction qubits, Potts, Parker, Baumberg & Groot, IEE Proceedings—Science, Measurement and Technology, vol. 148, pages 225-228, 2001. While the drawings depict a cross-type Josephson junction formed using a high aspect ratio resist, the method of the present invention can be applied to Josephson junctions formed by other methods, such as shadow evaporation using a suspended bridge (Niemeyer-Dolan technique) or by first forming a tri-layer including the first layer material, barrier material and second layer material and subsequently etching the tri-layer to form the Josephson junction 210.

The Josephson junction 210 is formed from a first layer 203, a barrier layer 205 and a second layer 204, also referred to as a second layer. Also formed on the substrate 201 are external electrodes 202a and 202b, to which the first layer 203 and second layer 204 of the Josephson junction 210 are connected by the bridge connections, which are formed in subsequent steps. The external electrodes 202a, 202b are “external” in the sense that they are used to form connections between the Josephson junction 210 and other electronic components or other circuits elements. The external electrodes 202a, 202b are external to the Josephson junction 210 in that they are not part of the Josephson junction 210 per se, i.e. they are not an integral part of the first layer 203 or second layer 204. However, the external electrodes 202a, 202b are used to form external connections to the Josephson junction 210, i.e. with other components. In other words, the first layer 203 and second layer 204 of the Josephson junction 210 are connected to the external electrodes 202a, 203b and only to the external electrodes 202a, 203a. The Josephson junction 210 may be spaced apart from the external electrodes 202a, 202b such that no part of the Josephson junction 210 is in direct contact with the external electrodes 202a, 202b. The first and second layers 203, 204 of the Josephson junction 210 may only be connected to other electronic components or other circuit elements via the external electrodes 202a, 202b. The first layer 203 of the Josephson junction 210 may be referred to as a “base electrode”, and the second layer 204 of the Josephson junction 210 may be referred to as a “counter electrode”.

FIG. 2B is a cross-section of the structure of FIG. 2A taken along the dashed line A.

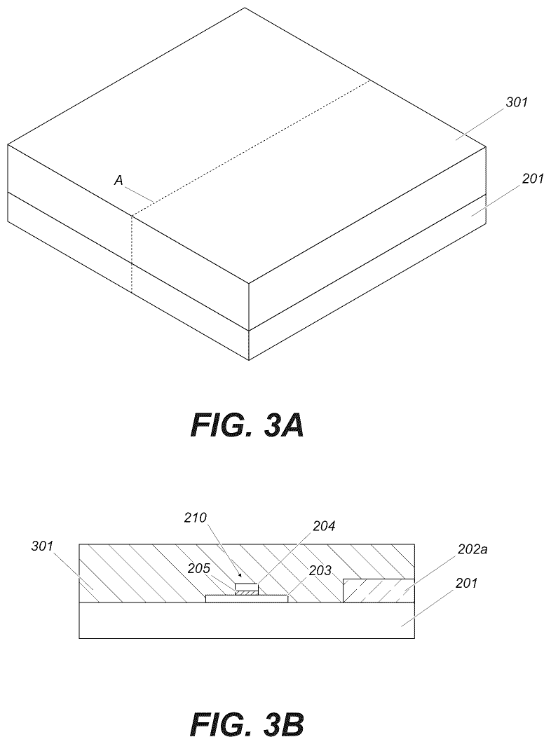

FIG. 3A is a perspective view of the substrate of FIG. 2A after a resist 301 has been formed on the upper surface. FIG. 3B is a cross-section of the structure shown in FIG. 3A taken along the dashed line A.

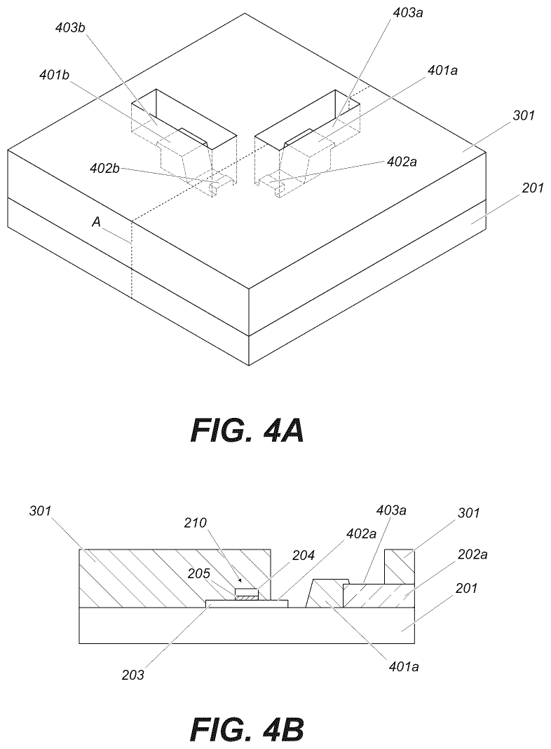

FIG. 4A is a perspective view of the substrate 201 and resist 301 shown in FIG. 3A after bridge connection support portions 401a, 401b have been formed in the resist 301. The bridge connection support portions 401a, 401b are formed by selectively removing resist material, for example by electron beam lithography or extended photolithography, to expose contact pads 402a, 402b on the first and second layers 203, 204 and 403a, 403b on the external electrodes 202a, 202b. Extended photolithography is described in Yuting Sun, Jiayu Ding, Xiaoyu Xia, Xiaohan Wang, Jianwen Xu, Shuqing Song, Dong Lan, Jie Zhao, and Yang Yu, “Fabrication of airbridges with gradient exposure”, Appl. Phys. Lett. 121, 074001 (2022).

First exposed Josephson junction contact pad 402a exposes a portion of the Josephson junction first layer 203 through the resist 301. Second exposed Josephson junction contact pad 402b exposes a portion of the Josephson junction second layer 204 though the resist 301. First exposed external electrode contact pad 403a exposes a portion of the first external electrode 202a through the resist 301. Second exposed external electrode contact pad 403b exposes a portion of the second external electrode 202b through the resist 301.

Bridge connection support portion 401a extends between the first exposed Josephson junction contact pad 402a and the first exposed external electrode contact pad 403a. Bridge connection support portion 401b extends between the second exposed Josephson junction contact pad 402b and the second exposed external electrode contact pad 403b.

The bridge connection support portions 401a, 401b define a trapezoidal shape with sloped sidewalls adjacent to the exposed contact pads 402a, 402b, 403a and 403b. The upper surface of the bridge connection support portions 401a, 401b is depicted as parallel to the surface of the substrate 201 and the surface of the resist 301, but this is not essential.

After the bridge connection support portions 401a, 401b and exposed contact pads 402a, 402b, 403a, 403b have been formed, a further wet etch or dry etch is performed in order to clean the exposed contact pads. A combination of wet and dry etching may alternatively be used to clean the exposed contact pads.

FIG. 4B is a cross-section of the structure shown in FIG. 4A taken along the dashed line A.

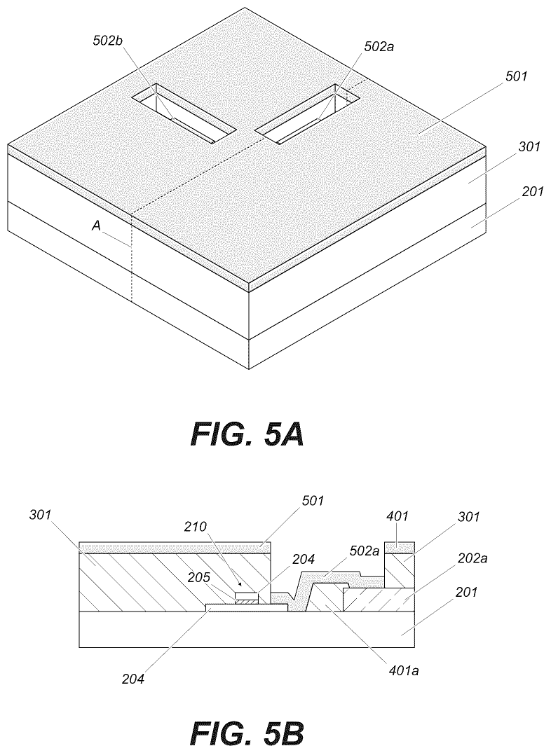

FIG. 5A is a perspective view of the substrate 201 and resist 301 shown in FIG. 4A after deposition of a superconducting thin film 501 over the resist 301, bridge connection support portions 401a, 401b and exposed contact pads 402a, 402b, 403a, 403b (shown in FIGS. 4A and 4B). The superconducting thin film may an aluminium thin film or any other suitable superconducting material. The superconducting thin film may be deposited by physical vapour deposition or chemical vapour deposition. Physical vapour deposition (sputtering) is preferred.

FIG. 5B is a cross-section of the structure shown in FIG. 5A taken along the dashed line A. As can be seen in FIG. 5B, the superconducting thin film is deposited within the opening in the resit 301 where the bridge connection support portion 401a is formed, creating a superconductive (when the superconducting material is below the critical temperature) connection 502a between the Josephson junction first layer 203 and the first external electrode 202a. Similarly, the superconducting thin film is also deposited within the opening in the resit 301 where the bridge connection support portion 401b is formed, creating a superconductive (when the superconducting material is below the critical temperature) connection 502b between the Josephson junction second layer 204 and the second external electrode 202b.

The shape of the superconductive connections 502a, 502b conforms to the shape of the exposed contact pads 402a, 402, 403a, 403b and bridge connection support portions 401a, 401b.

After deposition of the superconducting thin film, the resist 301, including bridge connection support portions 401a, 401b are removed for example using a suitable solvent. When the resist 301 is removed, the superconducting thin film 501 on top of the resist is no longer connected to the substrate 201 and it also removed. When the bridge connection support portions 401a, 401b are removed, the superconductive connections 502a, 502b remain connected to at least the first and second layers 203, 204 of the Josephson junction 210 and to the external electrodes 202a, 202b. Removal of the bridge connection support portions 401a, 401b therefore leaves a gap between the superconductive connections 502a, 502b and the substrate 201, the gap being located between the first and second layers 203, 204 of the Josephson junction 210 and the external electrodes 202a, 202b, as shown in FIGS. 6A and 6B. Specifically, a portion of the superconductive connection 502a is suspended above and separated from the substrate 201 between the Josephson junction first layer 203 and the external electrode 202a. The superconductive connection 502a thereby forms a first bridge connection 502a. Similarly, a portion of the superconductive connection 502b is suspended above and separated from the substrate 201 between the Josephson junction second layer 204 and the external electrode 202b. The superconductive connection 502b thereby forms a second bridge connection 502b.

FIG. 6A is a perspective view of the substrate 201, the Josephson junction 210 and the bridge connections 502a, 502b after lift-off of the resist 301, the bridge support portions 401a, 401b and the superconducting thin film 501. FIG. 6B is a cross-section of the structure shown in FIG. 6A taken along the dashed line A.

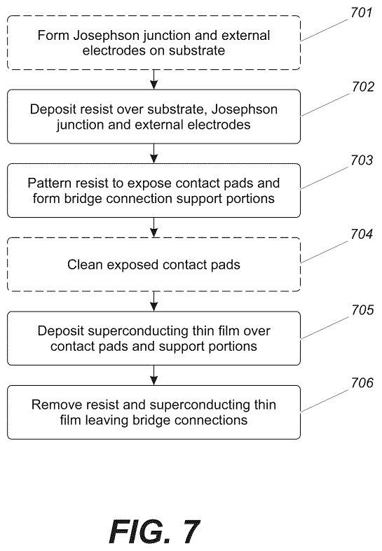

FIG. 7 is a flow diagram depicting a method of manufacturing an integrated circuit device according to the present invention. At step 701, a Josephson junction 210 and external electrodes 202a, 202b are fabricated on a substrate 201. The end result of step 701 corresponds to the structure shown in FIGS. 2A and 2B. Step 701 may be performed as part of the method of the present invention, or it may be performed separately before the method of the present invention begins at step 702.

At step 702, a resist is deposited over the substrate 201, the Josephson junction layers 203, 204, 205 and the external electrodes 202a, 202b. The end result of step 702 is depicted in FIGS. 3A and 3B.

At step 703, the resist is patterned to expose contact pads on the first layer 203 of the Josephson junction 210, the second layer 204 of the Josephson junction 210, the first external electrode 202a and the second external electrode 202b. The resist is also patterned to form the bridge connection support portions 401a and 401b, which are formed from the resist material by selectively removing the resist material to create the shape of the bridge connections support portions 401, 401b. Patterning the resist may be performed using electron beam lithography, extended photolithography, or any other suitable technique. The contact pads may be exposed and the bridge connection support structures formed in a single patterning step or across multiple distinct steps. The arrangement of the exposed contact pads 402a, 402b, 403a and 403b and bridge connection support portions 401a, 401b are described in more detail above with respect to FIGS. 4A and 4B which depict the end result of step 703.

At step 704, the method may include a separate step of cleaning the exposed contact pads, for example by wet etching, dry etching, or a combination of wet and dry etching. Depending on the technique used to pattern the resist in step 703, cleaning the exposed contact pads may be unnecessary, in which case it may not form part of the method.

At step 705, a superconducting thin film is deposited over the resist 301, including the bridge connection support portions 401a, 401b, and the exposed contact pads 402a, 402b, 403a, 403b. The end result of step 705 is depicted in FIGS. 5A and 5B and described in more detail above.

At step 706, the resist is removed, e.g. using a solvent, which causes the parts of the superconducting thin film 501 formed on top of the resist 301 to also be removed, while leaving behind the bridge connection structures 502a, 502b, which are connected to the exposed contact pads 402a, 402b, 403a and 403b as described above with respect to FIGS. 5A, 5B, 6A and 6B. FIGS. 6A and 6B depict the end result of step 706, which is described in more detail with respect to those drawings.

1. An integrated circuit device comprising:
a substrate;
a Josephson junction on the substrate;
external electrodes on the substrate and spaced apart from the Josephson junction; and
bridge connections connecting the Josephson junction to the external electrodes.

2. The integrated circuit device of claim 1, wherein the Josephson junction is a component of a superconducting qubit.

3. The integrated circuit device of claim 2, wherein the superconducting qubit is a transmon qubit, gmon qubit, or a fluxmon qubit.

4. The integrated circuit device of claim 2, wherein the integrated circuit device is a quantum processing unit.

5. The integrated circuit device of claim 1, wherein the Josephson junction was formed by shadow evaporation.

6. The integrated circuit device of claim 5, wherein the Josephson junction is a cross type Josephson junction.

7. The integrated circuit device of claim 1, wherein the Josephson junction is an Al/AlOₓ/Al junction.

8. The integrated circuit device of claim 1, wherein the Josephson junction is spaced apart from the external electrodes such that no part of the Josephson junction is in direct contact with the external electrodes.

9. The integrated circuit device of claim 1, wherein:
the Josephson junction comprises a first layer and a second layer;
a first bridge connection is in direct contact with the first layer of the Josephson junction and a first external electrode only; and
a second bridge connection is in direct contact with the second layer of the Josephson junction and second external electrode only.

10. The integrated circuit device of claim 9, wherein the first layer and the second layer of the Josephson junction comprise aluminium and wherein a barrier layer disposed between the first layer and the second layer comprises aluminium oxide.

11. A method of manufacturing an integrated circuit device, the method comprising:
forming a Josephson junction and external electrodes on a substrate such that the Josephson junction is spaced apart from the external electrodes;
depositing a resist over the substrate, the Josephson junction and the external electrodes;
patterning the resist such that contact pads on the Josephson junction and the external electrodes are exposed, and such that the patterned resist between the contact pads defines bridge connection support portions;
depositing a superconducting thin film over the resist such that the thin film is in direct electrical contact with the contact pads; and
forming bridge connections by removing the resist and the superconducting thin film except for the superconducting thin film deposited on the contact pads and over the bridge connection support portions.

12. The method of claim 11, wherein forming the external electrodes comprises depositing a metal layer on the substrate and patterning the metal layer to form the external electrodes and expose the substrate in areas not covered by the external electrodes.

13. The method of claim 11, wherein forming the Josephson junction comprises a double angle evaporation and lift-off process.

14. The method of claim 11, wherein the resist is patterned using electron beam lithography or extended photolithography.

15. The method of claim 11, wherein the method further comprises, prior to depositing the superconducting thin film, performing a wet-etch and/or dry-etch to clean the exposed contact pads.

16. The method of claim 11, wherein patterning the resist comprises exposing a first contact pad on a first layer of the Josephson junction, exposing a second contact pad on a second layer of the Josephson junction, exposing a third contact pad on a first external electrode, and exposing a fourth contact pad on a second external electrode.

17. The method of claim 16, wherein the patterned resist comprises a first bridge connection support portion extending between the first contact pad and the third contact pad, and a second bridge connection support portion extending between the second contact pad and the fourth contact pad.

18. The method of claim 17, wherein forming the bridge connections comprises:
forming a first bridge connection over the first bridge connection support portion, the first bridge connection being in direct contact with the first layer of the Josephson junction and the first external electrode only; and
forming a second bridge connection over the second bridge connection support portion, the second bridge connection being in direct contact with the second layer of the Josephson junction and the second external electrode only.

19. The method of claim 11, wherein the Josephson junction is spaced apart from the external electrodes such that no part of the Josephson junction is in direct contact with the external electrodes.

20. The method of claim 11, wherein a first layer and second layer of the Josephson junction comprise aluminium and wherein a barrier layer disposed between the first layer and second layer comprises aluminium oxide.

21. The method of claim 11, wherein the method further comprises forming further components of a superconducting qubit on the substrate.

22. An integrated circuit device produced by:
forming a Josephson junction and external electrodes on a substrate such that the Josephson junction is spaced apart from the external electrodes;
depositing a resist over the substrate, the Josephson junction and the external electrodes;
patterning the resist such that contact pads on the Josephson junction and the external electrodes are exposed, and such that the patterned resist between the contact pads defines bridge connection support portions;
depositing a superconducting thin film over the resist such that the thin film is in direct electrical contact with the contact pads; and
forming bridge connections by removing the resist and the superconducting thin film except for the superconducting thin film deposited on the contact pads and over the bridge connection support portions.
